(19) United States
(12) Patent Application Publication
(10) Pub. No.: US 2005/0074981 A1
(43) Pub. Date: Apr. 7, 2005

(54) Increasing the etch resistance of photoresists

(76) Inventors: Robert P. Meagley, Hillsboro, OR (US); Michael D. Goodner, Hillsboro, OR (US)

Correspondence Address: TROP PRUNER & HU, PC, 8554 KATY FREEWAY, SUITE 100, HOUSTON, TX, 77024, US

(21) Appl. No.: 10/679,793

(22) Filed: Oct. 6, 2003

(51) Int. Cl. H01L 21/302; H01L 21/461

(52) U.S. Cl. 438/745

(57) ABSTRACT

Materials may be utilized as photoresists which have relatively plasma poor etch resistance. Examples include acrylates and fluorinated polymers, which have very good transparency but poor etch resistance. Materials with relatively poor etch resistance may be first applied to the semiconductor wafer and patterned. After they have been patterned, their etch resistance may be improved. For example, the etch resistance may be improved by applying an absorbate which may be cross-linked or polymerized to increase the etch resistance of the already patterned material. Thereafter, the material with the improved etch resistance may be used as an etching mask.

### BACKGROUND

This invention relates generally to semiconductor processing and, particularly, to the formation of photoresists.

In patterning semiconductor wafers to form integrated circuits, photoresists are used. Photoresists are materials whose etchability may be altered by selectively exposing them to radiation. Photoresist, after exposure, is either harder or easier to remove by a development process. Thus, a pattern on a mask may be transferred to the semiconductor wafer by selectively exposing the photoresist. That pattern, once transferred to the resist, may then be subsequently utilized to form structures in the semiconductor wafer in a repeatable fashion using an etch process.

In modern lithography processes that make use of photoresist, the transparency of the photoresist becomes a critical issue. Traditional resist materials, such as phenolic resin (novolak) and polyvinylphenol (poly(hydroxy)styrene; PHOST), are opaque at relatively short wavelengths used in modern lithographic processes due to the presence of aromatic rings in such materials. However, these aromatic rings also provide the resist with good plasma etch resistance, due to the high carbon to total atom ratio of these aromatic rings, and as well from contributions due to the energy inherent to aromaticity (35 kcal/mol for benzene, for example).

New photoresist materials, not having aromatic moieties, inherently have lower etch resistance. Examples of the new types of material include acrylate and fluorinated polymers. These materials may be used for shorter wavelength radiation exposures such as 193 nanometers and 157 nanometer lithography systems.

Photoresist materials that have sufficient transparency to be advantageously used with new shorter exposure wavelengths, may not have sufficient etch resistance to be practical as photoresists.

Thus, there is a need for ways to increase the etch resistance of photoresists.

### BRIEF DESCRIPTION OF THE DRAWINGS

FIG. 1 is an enlarged, cross-sectional, schematic view of an early stage in accordance with one embodiment of the present invention;

FIG. 2 is an enlarged, cross-sectional, schematic view of the embodiment shown in FIG. 1 after further processing in accordance with one embodiment of the present invention;

FIG. 3 is an enlarged, cross-sectional, schematic view of the embodiment shown in FIG. 2 after further processing in accordance with one embodiment of the present invention; and

FIG. 4 is an enlarged, cross-sectional, schematic view of the embodiment shown in FIG. 3 after further processing in accordance with one embodiment of the present invention.

### DETAILED DESCRIPTION

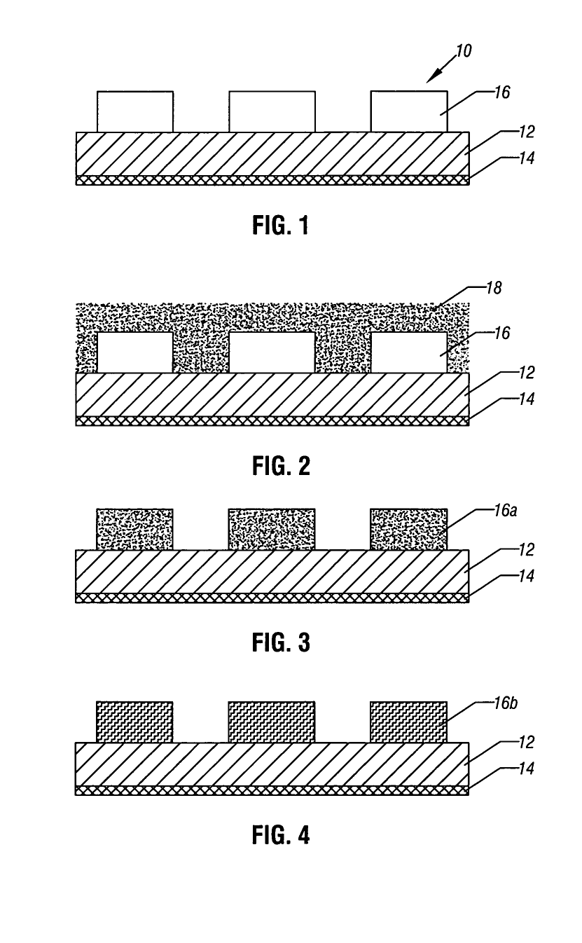

Referring to FIG. 1, a structure 14 may be covered with layers of material 12. It may be desirable to etch patterns in the material 12. To this end, a photoresist mask 16 may be formed on the material 12. Thus, the photoresist mask 16 may be applied and patterned using standard lithographic techniques. The structure 14 may, for example, be a semiconductor wafer such as a silicon wafer.

The material used for the photoresist mask 16 may be any of the highly transparent materials not having significant amounts of aromatic moieties, including acrylate and fluorinated polymers. Formed of acrylate, as used herein, includes acrylate-based polymers including acrylates, methacrylates, and other derivatives. The photoresist materials are in essence hydrophobic polymers. These materials, like most polymer films, can absorb small molecules from the environment. Providing intrinsically etch resistant species as an absorbate, imparts etch resistance to the already patterned photoresist 16.

In order to improve the etch resistance further, in situ polymerization of the absorbed species may be desirable. Thus, a polymer blend of the patterned photoresist resin and an etch resistant polymer, derived from the absorbate, may result. If the absorbate is capable of cross-linking, yet further durability and toughness may be imparted to the resist features upon formation of a semi-interpenetrating network.

Thus, referring to FIG. 2, the semiconductor structure 10, with the patterned photoresist mask 16, may be exposed to the absorbate 18, which may be in a gas phase, a liquid phase, a liquid solution or dispersion, or a supercritical fluid solution or dispersion in which a monomer is dissolved or dispersed in a supercritical fluid such as supercritical carbon dioxide. Once absorbed into the photoresist 16, the absorbate imparts etch resistance to the already patterned photoresist mask 16. Furthermore, the absorbate 18 may be polymerized or crosslinked in situ to provide additional etch resistance to the already patterned photoresist mask 16. The absorbate 18 in monomer vapor or monomer solution form may be provided to the photoresist mask 16 as shown in FIG. 2.

Referring to FIG. 3, the absorbate 18 has now been absorbed into the photoresist mask 16a. Any remaining absorbate 18 may be rinsed to remove excess material.

Referring to FIG. 4, once absorbed into the resist mask 16a, the absorbate 18 may be induced to polymerize and/or cross-link by several mechanisms to form the etch resistant material 16b. For example, in chemically amplified resist, the photogenerated acid in the resist 16a may initiate monomer reaction directly. Thermal treatment may also be used to decompose any remaining photoacid generator, thus providing acid moieties or other photoacid generator decomposition products that can initiate polymerization. Flood exposure of the resist features may be employed to increase the amount of acid initiated either before or after absorbate 18 introduction. Radicals generated either thermally or photochemically may also be employed as initiators of polymerization or cross-linking. Pretreatment of the resist features with initiator or initiator precursors may be employed either in advance of, in tandem with, or subsequent to the introduction of the absorbate 18.

Many materials condense upon polymerization with an increase in density. This density increase, relative to starting mask 16 density, is frequently accompanied by a reduction of physical size. Thus, if the absorbate polymerization is accompanied by an increase in density, it may also be accompanied by a decrease in size in some embodiments. Or, in other words, polymerization of the absorbate 18 into the photoresist mask 16 may induce a reduction in critical dimension, in addition to increasing etch resistance. Thus, in some embodiments, smaller features may be formed than would be possible with the limitations of existing lithographic processes.

In one embodiment, a non-reactive absorbate 18 may be an aromatic hydrocarbon derivative (such as naphthalene vapor) used as a gas phase treatment for positive tone 157 nanometer fluoropolymer-based photoresist patterns. Absorption of the absorbate into the photoresist pattern 16a provides improved etch resistance compared to the untreated feature 16. As another example, anthracene in alcohol (or other solvent which dissolves anthracene but does not dissolve the photoresist) may be used as a treatment for positive tone acrylate-type 193 nanometer photoresist patterns on silicon wafers.

In another embodiment, a polymerizable absorbate 18 may be a vinylbenzene derivative, such as divinylbenzene in hexane (or other solvent which dissolves divinylbenzene but does not dissolve the photoresist) used as a liquid phase treatment for positive tone 157 nanometer fluoropolymer-based photoresist patterns. The photoresist mask, formed on a silicon wafer, may be subjected to broadband ultraviolet flood exposure and baking to induce cross-linking of the absorbed monomer. In yet another example, styrene vapor may be used as a gas phase treatment for positive tone acrylate-type 193 nanometer photoresist patterns on silicon wafers. Spontaneous polymerization of the styrene may occur in situ with the photoresist upon heating.

When a cross-linking monomer is used, the resulting cross-linked polymer may be more difficult to strip as it is essentially one molecule that must be chemically attacked before dissolution can occur. However, resist strip chemicals exist that can specifically attack cross-linked photoresists. Examples of such chemicals include ALEG-820 and PRS-3000 (both available from Mallinckrodt Baker, Inc. Phillipsburg, N.J. 08865), to mention two examples.

As a result of impregnating the photoresist pattern with an absorbate, including possible cross-linking or polymerization, the resulting photoresist 16b has increased resistance to etching. Thus, it may be useful as an acceptable etching mask. The etch resistance may be decoupled from the patterning capability or transparency of the photoresist 16. Therefore, materials with good transparency, for example, may be used as photoresists even though they have poor etch resistance.

Absorbate penetration into the resist 16 may be engineered and tunable through time, temperature, pressure, concentration, solvent vehicle, absorbate structure, resist structure, resist density, and additives, to mention a few examples. Likewise, a degree of polymerization may be engineered and tunable through time, temperature, irradiation, additives such as initiators, and initiator concentration, to mention a few examples.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
exposing patterned photoresist to a material that is absorbed into the photoresist to increase its etch resistance.

2. The method of claim 1 wherein exposing includes exposing the patterned photoresist to a liquid comprising an absorbate.

3. The method of claim 1 wherein exposing includes exposing the patterned photoresist to a gaseous absorbate.

4. The method of claim 1 wherein exposing includes exposing said patterned photoresist to a supercritical fluid.

5. The method of claim 1 wherein exposing includes exposing a photoresist formed of acrylate to an absorbate to increase its etch resistance.

6. The method of claim 1 wherein exposing includes exposing a photoresist to an absorbate comprising anthracene in alcohol solution of to increase its etch resistance.

7. The method of claim 1 wherein exposing includes exposing a photoresist formed of fluoropolymer to an absorbate to increase its etch resistance.

8. The method of claim 1 wherein exposing includes exposing a photoresist to an absorbate comprising naphthalene vapor to increase its etch resistance.

9. A method comprising:
exposing patterned photoresist to a material that polymerizes the photoresist to increase its etch resistance.

10. The method of claim 9 wherein exposing the patterned photoresist includes exposing the patterned photoresist to a material that is absorbable by the photoresist to increase its etch resistance.

11. The method of claim 10 wherein exposing includes exposing the patterned photoresist to a liquid comprising an absorbate.

12. The method of claim 10 wherein exposing includes exposing the patterned photoresist to a gaseous absorbate.

13. The method of claim 10 wherein exposing includes exposing said patterned photoresist to a supercritical fluid.

14. The method of claim 9 wherein exposing said patterned photoresist includes reducing the physical size of the photoresist.

15. The method of claim 9 wherein exposing includes exposing a photoresist formed of acrylate to an absorbate to increase its etch resistance.

16. The method of claim 9 wherein exposing includes exposing a photoresist formed of fluoropolymer to an absorbate to increase its etch resistance.

17. A method comprising:
treating patterned photoresist with a crosslinking material to increase its etch resistance.

18. The method of claim 17 including causing a material to be absorbed into the patterned photoresist to crosslink said photoreist.

19. The method of claim 17 including polymerizing an absorbate in said patterned photoresist to increase its etch resistance.

20. The method of claim 17 including crosslinking an absorbate in said patterned photoresist to increase its etch resistance.

21. The method of claim 17 including crosslinking by exposure to vinylbenzene derivatives.

22. The method of claim 17 wherein treating includes exposing said patterned photoresist to a crosslinking monomer and stripping said crosslinked monomer using a resist stripper.

23. The method of claim 17 wherein exposing includes exposing a photoresist formed of acrylate to an absorbate to increase its etch resistance.

24. The method of claim 17 wherein exposing includes exposing a photoresist formed of fluoropolymer to an absorbate to increase its etch resistance.

25. A semiconductor wafer comprising:
a substrate; and
a patterned photoresist formed over said substrate, said patterned photoresist including an absorbate that increases etch resistance.

26. The wafer of claim 25 wherein said photoresist includes acrylate.

27. The wafer of claim 25 wherein said photoresist includes a fluorinated polymer.

28. The wafer of claim 25 wherein said photoresist is treated with an absorbate that polymerizes.

29. The wafer of claim 25 wherein said photoresist is treated with an absorbate that crosslinks.

30. The wafer of claim 25 wherein said absorbate is cross-linked.
